(19) United States
(12) Patent Application Publication
(10) Pub. No.: US 2024/0260352 A1
(43) Pub. Date: Aug. 1, 2024

(54) DISPLAY DEVICE

(71) Applicant: LG DISPLAY CO., LTD., Seoul (KR)

(72) Inventors: Taehwi KIM, Paju-si (KR); Jaesung KIM, Uijeongbu-si (KR)

(73) Assignee: LG DISPLAY CO., LTD., Seoul (KR)

(21) Appl. No.: 18/426,918

(22) Filed: Jan. 30, 2024

(30) Foreign Application Priority Data
Jan. 31, 2023 (KR) 10-2023-0013255

(51) Int. Cl. H10K 59/131

(52) U.S. Cl. CPC H10K 59/131

(57) ABSTRACT

A display device includes a display panel including an active area in which a plurality of pixels is disposed and a non-active area disposed to enclose the active area, a plurality of low potential auxiliary lines disposed in the active area, a plurality of low potential power lines which is connected to the plurality of low potential auxiliary lines and is disposed in the non-active area of the display panel, a plurality of data lines disposed in the active area and a plurality of data link lines which is disposed in the active area and transmits a data voltage to the plurality of data lines.

### CROSS-REFERENCE TO RELATED APPLICATION

This application claims the priority of Korean Patent Application No 10-2023-0013255 filed on Jan. 31, 2023, which is hereby incorporated by reference in its entirety.

### BACKGROUND

### Field of the Disclosure

The present disclosure relates to a display device, and more particularly, to a display device which is capable of improving rising of a low potential voltage.

### Description of the Background

Currently, as it enters a full-scale information era, a field of a display device which visually expresses electrical information signals has been rapidly developed and studies are continued to improve performances of various display devices such as thin-thickness, light weight, and low power consumption.

A representative display device may include a liquid crystal display (LCD) device, a field emission display (FED) device, an electro-wetting display (EWD) device, an organic light emitting display (OLED) device, and the like.

Among them, the organic light emitting display device is a self-emitting display device so that a separate light source is not necessary, which is different from the liquid crystal display device. Therefore, the organic light emitting display device may be manufactured to have a light weight and a small thickness. Further, since the organic light emitting display device is advantageous not only in terms of power consumption due to the low voltage driving, but also in terms of color implementation, a response speed, a viewing angle, and a contrast ratio (CR), it is expected to be utilized in various fields.

### SUMMARY

Accordingly, the present disclosure is directed to a display device that substantially achieves the desires described above.

More specifically, the present disclosure is to provide a display device which minimizes a bezel area.

The present disclosure is also to provide a display device which improves the voltage rising.

The present disclosure is not limited to the above-mentioned, and other features, which are not mentioned above, may be clearly understood by those skilled in the art from the following descriptions.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes a display panel including an active area in which a plurality of pixels is disposed and a non-active area disposed to enclose the active area, a plurality of low potential auxiliary lines disposed in the active area, a plurality of low potential power lines which is connected to the plurality of low potential auxiliary lines and is disposed in the non-active area of the display panel, a plurality of data lines disposed in the active area and a plurality of data link lines which is disposed in the active area and transmits a data voltage to the plurality of data lines.

Other detailed matters of the exemplary embodiments are included in the detailed description and the drawings.

According to the present disclosure, a link line disposed between a bending area and an active area is disposed in the active area and a low potential power line is disposed along a non-active area to minimize a bezel area.

According to the present disclosure, a low potential auxiliary line is additionally disposed in the active area to additionally apply a low potential power so that the voltage rising is improved to improve the imbalance of the color and the luminance.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary aspect of the present disclosure;

FIG. 2 is a block diagram of a gate driver of a display device according to an exemplary aspect of the present disclosure;

FIG. 3 is a cross-sectional view of a display panel of a display device according to an exemplary aspect of the present disclosure;

FIG. 4 is a circuit diagram of a pixel of a display device according to an exemplary aspect of the present disclosure;

FIGS. 5 and 6 are waveform diagrams for explaining operations of a scan signal and an emission control signal in a refresh period and a hold period in a pixel circuit illustrated in FIG. 4;

FIG. 7 is a plan view of a display panel of a display device according to an exemplary aspect of the present disclosure;

FIG. 8 is a plan view illustrating a low potential auxiliary line in a display panel of a display device according to an exemplary aspect of the present disclosure;

FIG. 9 is an enlarged view of a part of a display panel of a display device according to an exemplary aspect of the present disclosure;

FIG. 10 is an enlarged view illustrating part A1 of FIG. 8;

FIG. 11 is a cross-sectional view taken along line X-X′ of FIG. 10;

FIG. 12 is an enlarged view illustrating part A2 of FIG. 8;

FIG. 13 is a cross-sectional view taken along line XVI-XVI′ of FIG. 12;

FIG. 14 is an enlarged view illustrating part A3 of FIG. 8;

FIG. 15 is a cross-sectional view taken along line XVIII-XVIII′ of FIG. 14; and

FIG. 16 is a cross-sectional view of an outer periphery of a display panel of a display device according to an exemplary aspect of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure may be partially or entirely adhered to or combined with each other and may be interlocked and operated in technically various ways, and the embodiments may be carried out independently of or in association with each other.

Hereinafter, different embodiments of the present disclosure will be described in detail with reference to the attached drawings.

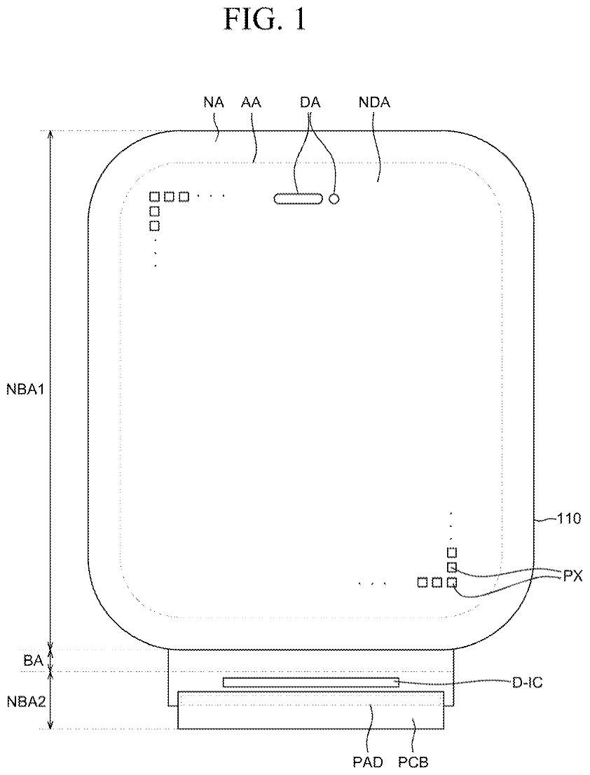

FIG. 1 is a plan view of a display device according to an exemplary aspect of the present disclosure.

Referring to FIG. 1, the display device 100 includes a display panel 110, a pad unit PAD, a gate driver, a driving integrated circuit D-IC, and a printed circuit board PCB.

In the display panel 110, an active area AA and the non-active area NA enclosing the active area AA may be defined. The active area AA is an area in which an image is actually displayed in the display device 100 and a light emitting diode to be described below and various driving elements for driving the light emitting diode may be disposed in the active area AA. The non-active area NA is an area where images are not displayed, and the non-active area NA may be defined as an area enclosing the active area AA. Various components for driving a plurality of pixels PX disposed in the active area AA may be disposed in the non-active area NA.

Referring to FIG. 1, the active area AA may include a non-optical area NDA and one or more optical areas DA. One or more optical areas DA may be areas overlapping one or more optical electronic devices. One or more optical electronic devices are electronic components disposed below the display panel 110 (an opposite side to a viewing surface). Light enters the front surface (viewing surface) of the display panel 110 and passes through the display panel 110 via the optical area DA to be transmitted to one or more optical electronic devices located below (an opposite side to a viewing surface) of the display panel 110. One or more optical electronic devices may be devices which receive light which passes through the display panel 110 to perform a predetermined function according to the received light. For example, the optical electronic device may include any one or more of a camera or a proximity sensor. Even though in FIG. 1, it is illustrated that the optical area DA has a circular or oval shape, the present disclosure is not limited thereto and the shape of the optical area DA may be an octagonal shape, and also may be various polygonal shapes.

The non-optical area NDA and one or more optical areas DA included in the active area AA are areas in which images may be displayed. The non-optical area NDA is an area in which there is no need to form a light transmission structure and one or more optical areas DA are areas in which the light transmission structure needs to be formed. Accordingly, one or more optical areas DA need to have a predetermined level or higher of transmittance and the non-optical area NDA does not have light transmissivity or has a transmittance lower than a predetermined level. For example, one or more optical areas DA and the non-optical area NDA may have different resolutions, sub pixel placement structures, numbers of sub pixels for every unit area, electrode structures, line structures, electrode placement structures, or line placement structures. For example, the number of sub pixels for every unit area in one or more optical areas DA may be smaller than the number of sub pixels for every unit area in the non-optical area NDA. That is, the resolution of one or more optical areas DA may be lower than a resolution of a non-optical area NDA. At this time, the number of sub pixels for every unit area is a unit of measuring a resolution and may be also pixels per inch (PPI) indicating the number of pixels within one inch.

Referring to FIG. 1, the display panel 110 may include a first non-bending area NBA1, a bending area BA which extends from one side of the active area AA to be bent, and a second non-bending area NBA2 which extends from one side of the bending area BA and includes a non-active area NA. The first non-bending area NBA1 is an area which corresponds to an active area AA in which a plurality of pixels PX is disposed and maintains a flat state. The second non-bending area NBA2 is an area opposite to the first non-bending area NBA1 and in the second non-bending area, a circuit element is disposed together with the driving integrated circuit D-IC and the printed circuit board PCB connected to the pad unit PAD are disposed and a flat state is maintained.

The bending area BA maintains a bent state. In the meantime, a notch formed by cutting both corners of the display panel 110 may be disposed in the bending area BA of the display panel 110. For example, a process of cutting a motherboard into panels, both side surfaces of the display panel 110 are cut to form the notch. Accordingly, an area of the display panel 110 to be disposed in the bending area BA is relatively reduced so that a stress to be applied to the display panel 110 may be reduced. In the meantime, to suppress the propagation of the crack which may occur during the cutting process, a crack prevention structure may be disposed in the display panel 110 along a cutting surface including the notch.

The pad unit PAD is disposed in the second non-bending area NBA2. The pad unit PAD may be electrically connected to the printed circuit board PCB to receive external power source and a data driving signal, or transmitting/receiving a touch signal. Accordingly, various driving signals, such as a driving signal and a data voltage may be supplied to the driving integrated circuit D-IC through the pad unit PAD.

The driving integrated circuit D-IC may be disposed in the second non-bending area NBA2. The driving integrated circuit D-IC may supply a data signal to the plurality of pixels PX. For example, the driving integrated circuit D-IC samples and latches the data signal supplied from the timing controller in response to a data timing control signal supplied from the timing controller to convert the data signal into a gamma reference voltage and output the converted gamma reference voltage. The driving integrated circuit D-IC may output a data signal through the plurality of data lines.

As the bending area BA is bent, the driving integrated circuit D-IC and the printed circuit board PCB connected to the pad unit PAD move toward the rear surface of the display panel 110 and may overlap the first non-bending area NBA1. Therefore, as seen from an upper portion of the display panel 110, the circuit element such as the driving integrated circuit D-IC and the printed circuit board PCB connected to the pad unit PAD may not be visible. Further, as the bending area BA is bent, the size of the non-active area NA visible from the upper portion of the display panel 110 is reduced so that a narrow bezel may be implemented.

In the first non-bending area NBA1, the gate driver may be disposed in the non-active area NA. The gate driver is disposed on a side surface of the active area AA to output a gate signal and an emission control signal under the control of the timing controller to select a pixel PX in which a data voltage is charged through a wiring line such as a gate line and an emission control signal line and adjust an emission timing. The gate driver shifts a scan signal and an emission control signal using a shift register to sequentially supply the gate signal and the emission control signals. The gate driver may be formed directly on the display panel 110, by a gate driver in panel (GIP) manner, but is not limited thereto.

A plurality of data lines which is connected to the driving integrated circuit D-IC to extend to the bending area BA and the first non-bending area NBA1 may be disposed. The plurality of data lines may transmit a signal applied to the driving integrated circuit D-IC to the pixel PX disposed in the active area AA.

A plurality of gate link lines which connects the driving integrated circuit D-IC and the gate driver may be disposed in the first non-bending area NBA1. The gate link line may transmit an external power transferred from the pad unit PAD to the gate driver disposed in the first non-bending area NBA1.

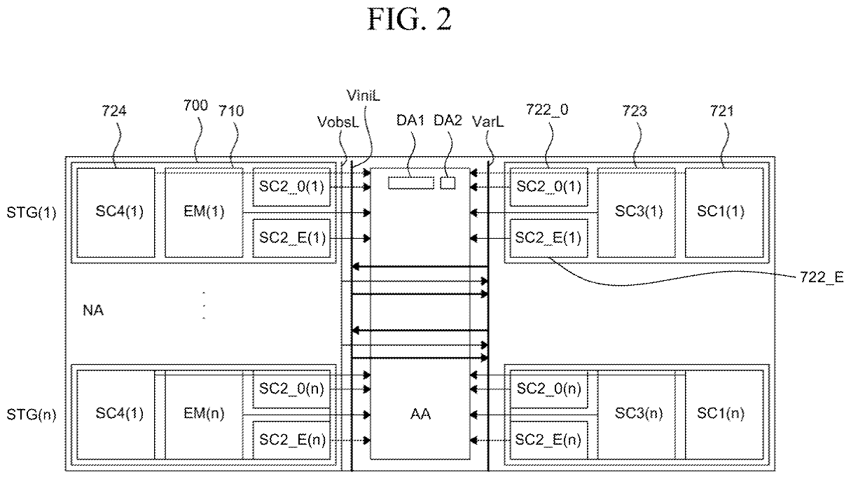

FIG. 2 is a block diagram of a gate driver of a display device according to an exemplary aspect of the present disclosure.

Referring to FIG. 2, the gate driver 700 includes an emission control signal driver 710 and scan drivers 721, 722, 723, and 724. The scan drivers 721, 722, 723, and 724 may be configured by first to fourth scan drivers 721, 722, 723, and 724. Further, the second scan driver 722 may be configured by an odd-numbered second scan driver 722_O and an even-numbered second scan driver 722_E.

In the gate driver 700, shift registers may be symmetrically disposed on both sides of the active area AA. Further, in the gate driver 700, a shift register at one side of the active area AA may include second scan drivers 722_O and 722_E, a fourth scan driver 724, and an emission control signal driver 710, respectively. A shift register at the other side of the active area AA may include a first scan driver 721, second scan drivers 722_O and 722_E, and a third scan driver 723, respectively. However, the present disclosure is not limited thereto and the emission control signal driver 710 and the first to fourth scan drivers 721, 722, 723, and 724 may be disposed in different ways according to the exemplary embodiments.

Each of stages STG1 to STGn of the shift register may include first scan signal generators SC1(1) to SC1(n), second scan signal generators SC2_O(1) to SC2_O(n), SC2_E(1) to SC2_E(n), third scan signal generators SC3(1) to SC3(n), fourth scan signal generators SC4(1) to SC4(n), and emission control signal generators EM(1) to EM(n), respectively.

The first scan signal generators SC1(1) to SC1(n) output first scan signals through first scan lines of the display panel 100. The second scan signal generators SC2(1) to SC2(n) output second scan signals through second scan lines of the display panel 100. The third scan signal generators SC3(1) to SC3(n) output third scan signals through third scan lines of the display panel 100. The fourth scan signal generators SC4(1) to SC4(n) output fourth scan signals through fourth scan lines of the display panel 100. The emission control signal generators EM(1) to EM output emission control signals through emission control lines of the display panel 100.

The first scan signals may be used as signals to drive an A-th transistor (for example, a compensation transistor) included in the pixel circuit. The second scan signals may be used as signals to drive a B-th transistor (for example, a data supply transistor) included in the pixel circuit. The third scan signals may be used as signals to drive a C-th transistor (for example, a bias transistor) included in the pixel circuit. The fourth scan signals may be used as signals to drive a D-th transistor (for example, an initialization transistor) included in the pixel circuit. The emission control signals may be used as signals to drive an E-th transistor (for example, an emission control transistor) included in the pixel circuit. For example, when the emission control transistor of the pixels is controlled using the emission control signals, an emission time of the light emitting diode varies.

Referring to FIG. 2, a bias voltage bus line VobsL, a first initialization voltage bus line VarL, and a second initialization voltage bus line ViniL may be disposed between the gate driver 700 and the active area AA.

The bias voltage bus line VobsL, the first initialization voltage bus line VarL, and the second initialization voltage bus line ViniL may supply a bias voltage Vobs, a first initialization voltage Var, and a second initialization voltage Vini to the pixel circuit, respectively.

In the drawing, it is illustrated that the bias voltage bus line VobsL, the first initialization voltage bus line VarL, and the second initialization voltage bus line ViniL are disposed on only one side of a left side or a right side of the active area AA, respectively, but the present disclosure is not limited thereto, and may be disposed on both sides. Further, even though the bias voltage bus line VobsL, the first initialization voltage bus line VarL, and the second initialization voltage bus line ViniL are disposed on one side, a left position or a right position is not limited.

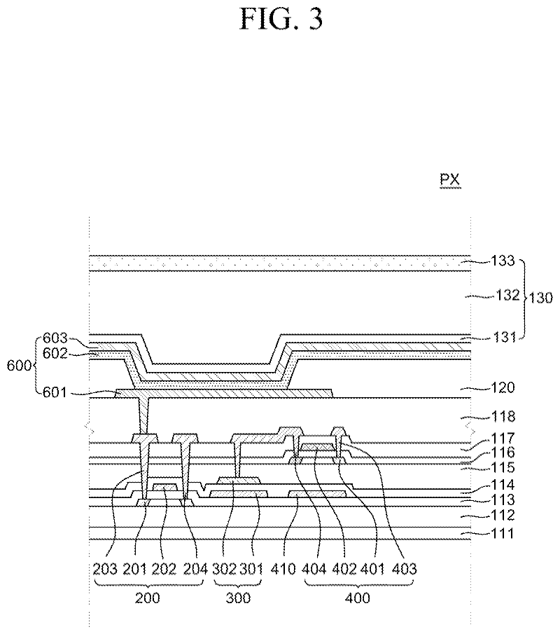

FIG. 3 is a cross-sectional view of a display panel of a display device according to an exemplary aspect of the present disclosure.

Referring to FIG. 3, FIG. 3 is a cross-sectional view including two thin film transistors 200 and 400 and one capacitor 300. Each of the two thin film transistors 200 and 400 may be switching thin film transistors including a polycrystalline semiconductor material or a driving thin film transistor including an oxide semiconductor material. In this case, the thin film transistor including the polycrystalline semiconductor material is referred to as a polycrystalline silicon thin film transistor and the thin film transistor including the oxide semiconductor material is referred to as an oxide thin film transistor.

The polycrystalline silicon thin film transistor 200 illustrated in FIG. 3 is an emission switching thin film transistor connected to the light emitting diode 600 and the oxide thin film transistor 400 is a switching thin film transistor connected to the capacitor 300.

One pixel PX includes a light emitting diode 600 and a pixel circuit which applies a driving current to the light emitting diode 600. The pixel circuit is disposed on the substrate 111 and the light emitting diode 600 is disposed on the pixel circuit. An encapsulation layer 130 is disposed on the light emitting diode 600. The encapsulation layer 130 protects the light emitting diode 600.

The pixel circuit may include a driving thin film transistor, a switching thin film transistor, and a capacitor. The light emitting diode 600 may include an anode electrode and a cathode electrode and an emission layer disposed therebetween to emit light.

In one exemplary aspect of the present disclosure, the driving thin film transistor and at least one switching thin film transistor use the oxide semiconductors as active layers. The thin film transistor which uses the oxide semiconductor material as an active layer has an excellent leakage current blocking effect and has a manufacturing cost which is cheaper than a thin film transistor which uses a polycrystalline semiconductor material as an active layer. Accordingly, to reduce the power consumption and save the manufacturing costs, the pixel circuit according to the exemplary aspect of the present disclosure includes a driving thin film transistor and at least one switching thin film transistor which use the oxide semiconductor material.

All the thin film transistors which configure the pixel circuit may be implemented using the oxide semiconductor material or only some switching thin film transistors may be implemented using the oxide semiconductor material.

However, it is difficult to ensure the reliability with the thin film transistor using the oxide semiconductor material, but the thin film transistor using a polycrystalline semiconductor material has a rapid operation speed and excellent reliability. Accordingly, the exemplary aspect of the present disclosure includes both the switching thin film transistor using the oxide semiconductor material and the switching thin film transistor using a polycrystalline semiconductor material.

The substrate 111 may be configured as multiple layers in which an organic layer and an inorganic layer are alternately laminated. For example, in the substrate 111, an organic layer such as polyimide and an inorganic layer such as silicon oxide (SiO₂) may be alternately laminated.

A lower buffer layer 112 is formed on the substrate 111. The lower buffer layer 112 is provided to block moisture, and the like penetrating from the outside and may be used by laminating a plurality of silicon oxide (SiO₂) layers. Au auxiliary buffer layer may be further disposed on the lower buffer layer 112 to protect the element from the moisture permeation.

The polycrystalline silicon thin film transistor 200 is formed on the substrate 111. The polycrystalline silicon thin film transistor 200 may use the polycrystalline semiconductor as an active layer. The polycrystalline silicon thin film transistor 200 includes a first active layer 201 including a channel through which electrons or holes move, a first gate electrode 202, a first source electrode 203, and a first drain electrode 204.

The first active layer 201 includes a first channel area, a first source area which is disposed on one side of the first channel area and a first drain area disposed on the other side. The first source area and the first drain area are disposed with the first channel area therebetween.

The first source area and the first drain area are areas in which an intrinsic polycrystalline semiconductor material is doped with group 5 or group 3 impurity ions, for example, phosphorus (P) or boron (B) at a predetermined concentration to be conductive. In the first channel area, the polycrystalline semiconductor material maintains an intrinsic state and a path through which the electrons or holes move is provided.

In the meantime, the polycrystalline silicon thin film transistor 200 includes a first gate electrode 202 which overlaps the first channel area of the first active layer 201. A first gate insulating layer 113 is disposed between the first gate electrode 202 and the first active layer 201. The first gate insulating layer 113 may be a single layer or multiple layers formed by laminating inorganic layers, such as a silicon oxide (SiO₂) film and silicon nitride (SiNx).

In the exemplary aspect of the present disclosure, the polycrystalline silicon thin film transistor 200 has a top gate structure in which the first gate electrode 202 is located above the first active layer 201. Accordingly, the first electrode 301 included in the capacitor 300 and a light shielding layer 410 included in the oxide thin film transistor 400 may be formed with the same material as the first gate electrode 202. The first gate electrode 202, the first electrode 301, and the light shielding layer 410 are formed by one mask process so that the number of mask processes may be reduced.

The first gate electrode 202 is formed of a metal material. For example, the first gate electrode 202 may be a single layer or multiple layers formed of one of molybdenum (Mo), aluminum (Al), chrome (Cr), gold (Au), titanium (Ti), nickel (Ni), neodymium (Nd), and copper (Cu) or an alloy thereof, but is not limited thereto.

A first interlayer insulating layer 114 is disposed on the first gate electrode 202. The first interlayer insulating layer 114 may be formed of silicon oxide SiO₂, silicon nitride SiNx, or the like.

The polycrystalline silicon thin film transistor 200 may further include an upper buffer layer 115, a second gate insulating layer 116, and a second interlayer insulating layer 117 which are sequentially disposed on the first interlayer insulating layer 114 and includes a first source electrode 203 and a first drain electrode 204. The first source electrode 203 and the first drain electrode 204 are formed on the second interlayer insulating layer 117 and are connected to the first source area and the first drain area, respectively.

The first source electrode 203 and the first drain electrode 204 may be formed of a single layer or multiple layers formed of one of molybdenum (Mo), aluminum (Al), chrome (Cr), gold (Au), titanium (Ti), nickel (Ni), neodymium (Nd), and copper (Cu) or an alloy thereof, but are not limited thereto.

The upper buffer layer 115 separates the second active layer 401 of the oxide thin film transistor 400 implemented by an oxide semiconductor material from the first active layer 201 implemented by a polycrystalline semiconductor material and provides a base for forming the second active layer 401.

The second gate insulating layer 116 covers the second active layer 401 of the oxide thin film transistor 400. The second gate insulating layer 116 is formed on the second active layer 401 implemented by the oxide semiconductor material so that the second gate insulating layer is implemented by an inorganic film. For example, the second gate insulating layer 116 may be silicon oxide SiO₂, silicon nitride SiNx, or the like.

The second gate electrode 402 is formed of a metal material. For example, the second gate electrode 402 may be formed of a single layer or multiple layers formed of any one of molybdenum (Mo), aluminum (Al), chrome (Cr), gold (Au), titanium (Ti), nickel (Ni), neodymium (Nd), and copper (Cu) or an alloy thereof, but is not limited thereto.

In the meantime, the oxide thin film transistor 400 is formed on the upper buffer layer 115 and includes a second active layer 401 which is implemented by the oxide semiconductor material, a second gate insulating layer 116 which covers the second active layer 401, a second gate electrode 402 disposed on the second gate insulating layer 116, a second interlayer insulating layer 117 which covers the second gate electrode 402, and a second source electrode 403 and a second drain electrode 404 disposed on the second interlayer insulating layer 117.

The second active layer 401 is implemented by the oxide semiconductor material and includes an intrinsic second channel area which is not doped with an impurity and a second source area and a second drain area which are doped with an impurity to become conductive.

The oxide thin film transistor 400 further includes a light shielding layer 410 which is located below the upper buffer layer 115 and overlaps the second active layer 401. The light shielding layer 410 blocks light incident onto the active layer 401 to ensure the reliability of the oxide thin film transistor 400. The light shielding layer 410 may be formed by the same material as the first gate electrode 202 and may be formed on an upper surface of the first gate insulating layer 113. The light shielding layer 410 is electrically connected to the second gate electrode 402 to configure a dual gate.

The second source electrode 403 and the second drain electrode 404 are simultaneously formed of the same material as the first source electrode 203 and the first drain electrode 204 on the second interlayer insulating layer 117 to reduce the number of mask processes.

In the meantime, the second electrode 302 is disposed on the first interlayer insulating layer 114 to overlap the first electrode 301 to implement a capacitor 300. For example, the second electrode 302 may be a single layer or multiple layers formed of any one of molybdenum (Mo), aluminum (Al), chrome (Cr), gold (Au), titanium (Ti), nickel (Ni), neodymium (Nd), and copper (Cu), or an alloy thereof.

The capacitor 300 stores a data voltage which is applied through the data line DL for a predetermined period and then supplies the data voltage to the light emitting diode 600. The capacitor 300 includes two corresponding electrodes and a dielectric material disposed therebetween. The first interlayer insulating layer 114 is located between the first electrode 301 and the second electrode 302.

The first electrode 301 or the second electrode 302 of the capacitor 300 may be electrically connected to the second source electrode 403 or the second drain electrode 404 of the oxide thin film transistor 400. However, it is not limited thereto and a connection relationship of the capacitor 300 may vary according to the pixel circuit.

In the meantime, a planarization layer 118 is disposed on the pixel circuit to planarize an upper end of the pixel circuit. The planarization layer 118 may be an organic film formed of such as polyimide and acrylic resin.

The light emitting diode 600 is formed on the planarization layer 118.

The light emitting diode 600 includes an anode electrode 601, a cathode electrode 603, and an emission layer 602 disposed between the anode electrode 601 and the cathode electrode 603. If a pixel circuit which commonly uses a low potential voltage connected to the cathode electrode 603 is implemented, the anode electrode 601 is disposed as a separate electrode in every sub pixel. If a pixel circuit which commonly uses a high potential voltage is implemented, the cathode electrode 603 may be disposed as a separate electrode in every sub pixel.

The light emitting diode 600 is electrically connected to a driving element through a contact hole. Specifically, the anode electrode 601 of the light emitting diode 600 is connected to the first source electrode 203 of the polycrystalline silicon thin film transistor 200 which configures the pixel circuit through the contact hole.

The anode electrode 601 may be formed to have a multi-layered structure including a transparent conductive film and an opaque conductive film having high reflection efficiency. The transparent conductive film may be configured with a material having a relatively high work function, such as indium-tin-oxide (ITO) and indium-zinc-oxide (IZO) and the opaque conductive film may be configured as a single- or multi-layered structure including aluminum (Al), silver (Ag), copper (Cu), lead (Pb), molybdenum (Mo), titanium (Ti), or an alloy thereof. For example, the anode electrode 601 may be formed with a structure in which a transparent conductive film, an opaque conductive film, and a transparent conductive film are sequentially laminated or may be formed with a structure in which a transparent conductive film and an opaque conductive film are sequentially laminated.

The emission layer 602 may be formed by laminating a hole-related layer, an organic emission layer, and an electron-related layer on the anode electrode 601 in this order or in a reverse order.

A bank layer 120 may be a pixel definition layer which exposes the anode electrode 601 of each pixel PX. The bank layer 120 may be formed of an opaque material (for example, black) to suppress the light interference between adjacent pixels PX.

The cathode electrode 603 is formed on a top surface and a side surface of the emission layer 602 to be opposite to the anode electrode 601 with the emission layer 602 therebetween. The cathode electrode 603 may be integrally formed on the overall active area AA. When the cathode electrode 603 is applied to a top-emission type organic light emitting display device, the cathode electrode may be configured by a transparent conductive film, such as indium-tin-oxide (ITO) and indium-zinc-oxide (IZO).

An encapsulation layer 130 may be further disposed on the cathode electrode 603 to suppress moisture permeation. The encapsulation layer 130 may include a first inorganic encapsulation layer 131, an organic encapsulation layer 132, and a second inorganic encapsulation layer 133 which are sequentially laminated.

The first inorganic encapsulation layer 131 and the second inorganic encapsulation layer 133 of the encapsulation layer 130 may be formed of an inorganic material, such as silicon oxide (SiOx). The organic encapsulation layer 132 of the encapsulation layer 130 may be formed of an organic material, such as acryl resin, epoxy resin, phenolic resin, polyamide resin, and polyimide resin.

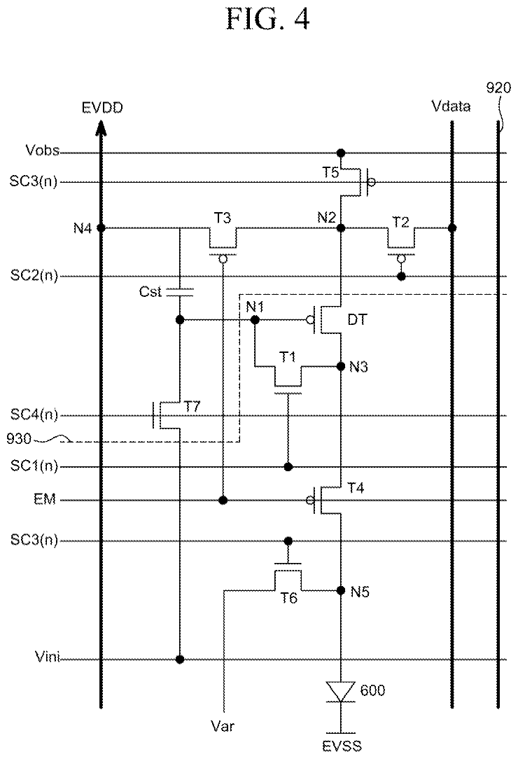

FIG. 4 is a circuit diagram of a pixel of a display device according to an exemplary aspect of the present disclosure.

FIG. 4 exemplarily illustrates the pixel circuit for description and it is not specifically limited as long as the structure may control the emission of the light emitting diode 600 by applying the emission signal EM. For example, the pixel circuit may include an additional scan signal, a switching thin film transistor connected thereto, and a switching thin film transistor to which an additional initialization voltage is applied. Further, a connection relationship of a switching element or a connection location of a capacitor may be also disposed in various manners. Hereinafter, for the convenience of description, a display device with a pixel circuit structure of FIG. 4 will be described.

Referring to FIG. 4, each of the plurality of pixels PX may include a pixel circuit having a driving transistor DT and a light emitting diode 600 connected to the pixel circuit.

The pixel circuit controls the driving current which flows in the light emitting diode 600 to drive the light emitting diode 600. The pixel circuit may include the driving transistor DT, first to seventh transistors T1 to T7, and the capacitor Cst. Each of the transistors DT, T1 to T7 may include a first electrode, a second electrode, and a gate electrode. One of the first electrode and the second electrode may be a source electrode and the other one of the first electrode and the second electrode may be a drain electrode.

Each of the transistors DT, T1 to T7 may be a P-type thin film transistor or an N-type thin film transistor. In the exemplary aspect of FIG. 4, the first transistor T1 and the seventh transistor T7 are N-type thin film transistors and the remaining transistors DT, T2 to T6 are P-type thin film transistors. However, it is not limited thereto and depending on the exemplary aspect, all or some of the transistors DT, T1 to T7 may be P-type thin film transistors or N-type thin film transistors. Further, the N-type thin film transistor may be an oxide thin film transistor and the P-type thin film transistor may be a polycrystalline silicon thin film transistor.

Hereinafter, it is exemplified that the first transistor T1 and the seventh transistor T7 are N-type thin film transistors and the remaining transistors DT, T2 to T6 are P-type thin film transistors. Accordingly, a high voltage is applied to the first transistor T1 and the seventh transistor T7 to be turned on and a low voltage is applied to the remaining transistors DT, T2 to T6 to be turned on.

According to the exemplary aspect, the first transistor T1 which configures the pixel circuit may serve as a complementary transistor, the second transistor T2 may serve as a data supply transistor, the third and fourth transistors T3 and T4 may serve as emission control transistors, and the fifth transistor T5 may serve as a bias transistor. Further, the sixth and seventh transistors T6 and T7 may serve as initialization transistors.

The light emitting diode 600 may include an anode electrode and a cathode electrode. The anode electrode of the light emitting diode 600 may be connected to a fifth node N5 and the cathode electrode may be connected to a low potential power voltage EVSS.

The driving transistor DT may include a first electrode connected to a second node N2, a second electrode connected to a third node N3, and a gate electrode connected to a first node N1. The driving transistor DT may provide a driving current to the light emitting diode 600 based on a voltage of the first node N1 (or a data voltage stored in the capacitor Cst to be described below).

The first transistor T1 may include a first electrode connected to the first node N1, a second electrode connected to the third node N3, and a gate electrode which receives a first scan signal SC1. The first transistor T1 is turned on in response to the first scan signal SC1 and is diode-connected between the first node N1 and the third node N3 to sample a threshold voltage Vth of the driving transistor DT. Such a first transistor T1 may be a compensation transistor.

The capacitor Cst may be connected or formed between the first node N1 and a fourth node N4. The capacitor Cst may store or maintain the supplied high potential power voltage EVDD.

The second transistor T2 may include a first electrode which receives a data voltage Vdata, a second electrode connected to the second node N2, and a gate electrode which receives a second scan signal SC2. The second transistor T2 is turned on in response to the second scan signal SC2 and may transmit the data voltage Vdata to the second node N2. Such a second transistor T2 may be a data supply transistor.

The third transistor T3 and the fourth transistor T4 are connected between the high potential power voltage EVDD and the light emitting diode 600 and may form a current movement path through which a driving current generated by the driving transistor DT moves.

The third transistor T3 may include a first electrode which is connected to the fourth node N4 to receive a high potential power voltage EVDD, a second electrode connected to the second node N2, and a gate electrode which receives an emission control signal EM.

The fourth transistor T4 may include a first electrode connected to the third node N3, a second electrode connected to the fifth node N5, and a gate electrode which receives the emission control signal EM.

The third and fourth transistors T3 and T4 are turned on in response to the emission control signal EM and in this case, the driving current is supplied to the light emitting diode 600 and the light emitting diode 600 may emit light with a luminance corresponding to the driving current Id.

The fifth transistor T5 may include a first electrode which receives a bias voltage Vobs, a second electrode connected to the second node N2, and a gate electrode which receives a third scan signal SC3. Such a fifth transistor T5 may be a bias transistor.

The sixth transistor T6 may include a first electrode which receives a first initialization voltage Var, a second electrode connected to the fifth node N5, and a gate electrode which receives the third scan signal SC3.

The sixth transistor T6 is turned on in response to the third scan signal SC3, before the light emitting diode 600 emits light (or after the light emitting diode 600 emits light) and may initialize the anode electrode (or the pixel electrode) of the light emitting diode 600 using the first initialization voltage Var. The light emitting diode 600 may have a parasitic capacitor formed between the anode electrode and the cathode electrode. The parasitic capacitor is charged while the light emitting diode 600 emits light so that the anode electrode of the light emitting diode 600 may have a specific voltage. Accordingly, the first initialization voltage Var is applied to the anode electrode of the light emitting diode 600 through the sixth transistor T6 to initialize a quantity of charges accumulated in the light emitting diode 600.

In the present disclosure, the gate electrodes of the fifth and sixth transistors T5 and T6 are configured to commonly receive the third scan signal SC3. However, the present disclosure is not limited thereto and the gate electrodes of the fifth and sixth transistors T5 and T6 may be configured to receive separate scan signals to be independently controlled.

The seventh transistor T7 may include a first electrode which receives a second initialization voltage Vini, a second electrode connected to the first node N1, and a gate electrode which receives a fourth scan signal SC4.

The seventh transistor T7 is turned on in response to the fourth scan signal SC4 and may initialize the gate electrode of the driving transistor DT using the second initialization voltage Vini. In the gate electrode of the driving transistor DT, unnecessary charges may remain due to the high potential power voltage EVDD stored in the capacitor Cst. Accordingly, the second initialization voltage Vini is applied to the gate electrode of the driving transistor DT through the seventh transistor T7 to initialize the remaining quantity of charges.

In the meantime, referring to FIG. 4, low potential auxiliary lines 920 and 930 may be disposed in each of the plurality of pixels PX. At this time, the low potential auxiliary lines 920 and 930 may be disposed to overlap the pixel circuit to pass through the pixel circuit. The low potential auxiliary lines 920 and 930 will be described in detail below.

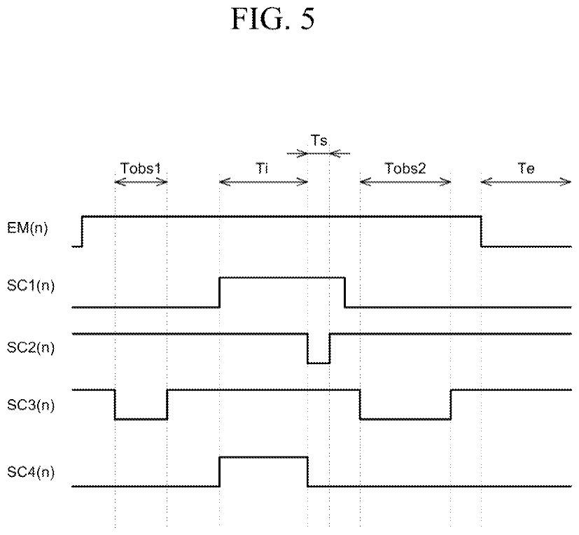

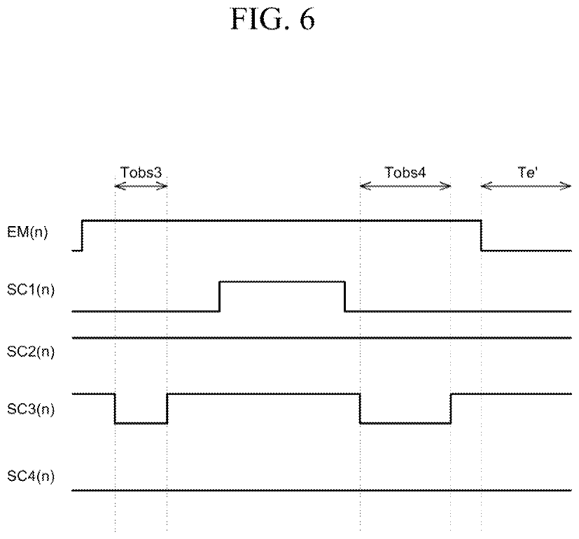

FIGS. 5 and 6 are waveform diagrams for explaining operations of a scan signal and an emission control signal in a refresh period and a hold period in a pixel circuit illustrated in FIG. 4.

The display device 100 according to the exemplary aspect of the present disclosure may operate as a variable refresh rate (VRR) mode display device. In the VRR mode, the pixel is driven at a constant frequency and at the moment when a high speed driving is necessary, a refresh rate at which the data voltage Vdata is updated is increased to operate the pixel or at a moment when the power consumption needs to be lowered or low-speed driving is necessary, the refresh rate is lowered to operate the pixel.

Each of the plurality of pixels PX may be driven by a combination of a refresh frame and a hold frame in one second. In the present disclosure, one set is defined that a combination of a refresh period in which the data voltage Vdata is updated and a hold period in which the data voltage Vdata is not updated is repeated for one second. One set period is a period in which a combination of the refresh period and the hold period is repeated.

When the refresh rate is driven at 120 Hz, it may be driven only with the refresh period. That is, the refresh period may be driven 120 times in one second. One refresh period is 1/120=8.33 ms and one set period is also 8.33 ms.

When the refresh rate is driven at 60 Hz, the refresh period and the hold period may be alternately driven. That is, the refresh period and the hold period may be alternately driven 60 times each in one second. One refresh period and one hold period are 0.5/60=8.33 ms, respectively, and one set period is 16.66 ms.

When the refresh rate is driven at 1 Hz, one frame may be driven with one refresh period and 119 hold periods after the one refresh period. Further, when the refresh rate is driven at 1 Hz, one frame may be driven with a plurality of refresh periods and a plurality of hold periods. At this time, one refresh period and one hold period are 1/120=8.33 ms, respectively, and one set period is 1 s.

In the refresh period, a new data voltage Vdata is charged to apply a new data voltage Vdata to the driving transistor DT and in the hold period, a data voltage Vdata of a previous frame is held to be used as it is. In the meantime, in the hold period, a process of applying the new data voltage Vdata to the driving transistor DT is omitted so that the hold period is also referred to as a skip period.

Each of the plurality of pixels PX may initialize a voltage which is charged or remains in the pixel circuit during the refresh period. Specifically, each of the plurality of pixels PX may remove the influence of the data voltage Vdata and the high potential power voltage EVDD stored in the previous frame in the refresh period. Accordingly, each of the plurality of pixels PX may display an image corresponding to a new data voltage Vdata in the hold period.

Each of the plurality of pixels PX supplies a driving current corresponding to the data voltage Vdata to the light emitting diode 600 to display images and may maintain a turned-on state of the light emitting diode 600, during the hold period.

First, the driving of the pixel circuit and the light emitting diode in the refresh period of FIG. 5 will be described. The refresh period may include at least one bias interval Tobs1 and Tobs2, an initialization interval Ti, a sampling interval Ts, and an emission interval Te, but this is just an exemplary aspect and is not necessarily bound to this order.

Referring to FIG. 5, the pixel circuit may operate including at least one bias interval Tobs1 and Tobs2 during the refresh period.

At least one bias interval Tobs1 and Tobs2 is a period in which an on-bias stress operation OBS to apply a bias voltage Vobs is performed, the emission control signal EM is a high voltage, and the third and fourth transistors T3 and T4 are turned off. The first scan signal SC1 and the fourth scan signal SC4 are low voltages and the first transistor T1 and the seventh transistor T7 are turned off. The second scan signal SC2 is a high voltage and the second transistor T2 is turned off.

The third scan signal SC3 is input as a low voltage and the fifth and sixth transistors T5 and T6 are turned on. As the fifth transistor T5 is turned on, the bias voltage Vobs is applied to the first electrode of the driving transistor DT connected to the second node N2.

Here, the bias voltage Vobs is supplied to the third node N3 which is a drain electrode of the driving transistor DT so that a charging time or charging delay of the voltage of the fifth node N5 which is the anode electrode of the light emitting diode 600 in the emission period may be reduced. The driving transistor DT maintains a stronger saturation state.

For example, the higher the bias voltage Vobs, the higher the voltage of the third node N3 which is the drain electrode of the driving transistor DT and the lower the gate-source voltage or the drain-source voltage of the driving transistor DT. Accordingly, the bias voltage Vobs is desirably at least higher than the data voltage Vdata.

At this time, the magnitude of the drain-source current Id which passes through the driving transistor DT may be reduced and in a positive bias stress situation, the stress of the driving transistor DT is reduced to solve the charging delay of the voltage of the third node N3. In other words, before sampling a threshold voltage Vth of the driving transistor DT, the on-bias stress operation OBS is performed to relieve the hysteresis of the driving transistor DT.

Accordingly, in at least one bias interval Tobs1 and Tobs2, the on-bias stress operation OBS may be defined as an operation of directly applying an appropriate bias voltage to the driving transistor DT during non-emission periods.

Further, in at least one bias interval Tobs1 and Tobs2, the sixth transistor T6 is turned on so that the anode electrode of the light emitting diode 600 connected to the fifth node N5 is initialized with the first initialization voltage Var.

However, the gate electrodes of the fifth and sixth transistors T5 and T6 may be configured to receive separate scan signals to be independently controlled. That is, it is not required to necessarily simultaneously apply the bias voltage to the first electrode of the driving transistor DT and the anode electrode of the light emitting diode 600 in the bias interval.

Referring to FIG. 5, the pixel circuit may operate including the initialization interval Ti during the refresh period. The initialization interval Ti is an interval in which the voltage of the gate electrode of the driving transistor DT is initialized.

The first scan signal SC1 to the fourth scan signal SC4 and the emission control signal EM are high voltages and the first transistor T1 and the seventh transistor T7 are turned on. The second to sixth transistors T2, T3, T4, T5, and T6 are turned off. As the first and seventh transistors T1 and T7 are turned on, the gate electrode of the driving transistor DT and the second electrode connected to the first node N1 are initialized with the second initialization voltage Vini.

Referring to FIG. 5, the pixel circuit may operate including the sampling interval Ts during the refresh period. The sampling interval is an interval in which the threshold voltage Vth of the driving transistor DT is sampled.

The first scan signal SC1, the third scan signal SC3, and the emission control signal EM are high voltages and the second scan signal SC2 and the fourth scan signal SC4 are low voltages. Accordingly, the third to seventh transistors T3, T4, T5, T6, and T7 are turned off, the first transistor T1 maintains an on-state, and the second transistor T2 is turned on. That is, the second transistor T2 is turned on to apply the data voltage Vdata to the driving transistor DT and the first transistor T1 is diode-connected between the first node N1 and the third node N3 to sample the threshold voltage Vth of the driving transistor DT.

Referring to FIG. 5, the pixel circuit may operate including emission interval Te during the refresh period. The emission interval Te is an interval in which the sampled threshold voltage Vth is cancelled and the driving current corresponding to the sampled data voltage allows the light emitting diode 600 to emit light.

The emission control signal EM is a low voltage and the third and fourth transistors T3 and T4 are turned on.

As the third transistor T3 is turned on, the high potential power voltage EVDD connected to the fourth node N4 is applied to the first electrode of the driving transistor DT connected to the second node N2 through the third transistor T3. The driving current which is supplied from the driving transistor DT to the light emitting diode 600 via the fourth transistor T4 becomes independent of the value of the threshold voltage Vth of the driving transistor DT so that the threshold voltage Vth of the driving transistor DT is compensated for operation.

Next, the driving of the pixel circuit and the light emitting diode during the hold period will be described with reference to FIG. 6.

The hold period may include at least one bias interval Tobs3 and Tobs4 and the emission interval Te′. The same operation of the pixel circuit as the operation of the refresh period will not be described.

As described above, in the refresh period, a new data voltage Vdata is charged to apply a new data voltage Vdata to the gate electrode of the driving transistor DT, but in the hold period, the data voltage Vdata of the refresh period is held to be used as it is. Accordingly, the hold period does not require the initialization interval Ti and the sampling interval Ts, unlike the refresh period.

In the operation of the hold period, a single on-bias stress operation OBS may be sufficient. However, in the exemplary aspect, for the convenience of the driving circuit, the third scan signal SC3 of the hold period is driven as the same as the third scan signal SC3 of the refresh period so that the on-bias stress operation OBS may operate twice as in the refresh period.

The difference between the driving in the refresh period which has been described with reference to FIG. 5 and the driving signal of the hold period in FIG. 6 is the second and fourth scan signals SC2 and SC4. In the hold period, the initialization interval Ti and the sampling interval Ts are not necessary so that unlike the refresh period, the second scan signal SC2 is always a high voltage and the fourth scan signal SC4 is always a low voltage. That is, the second and seventh transistors T2 and T7 are always turned off.

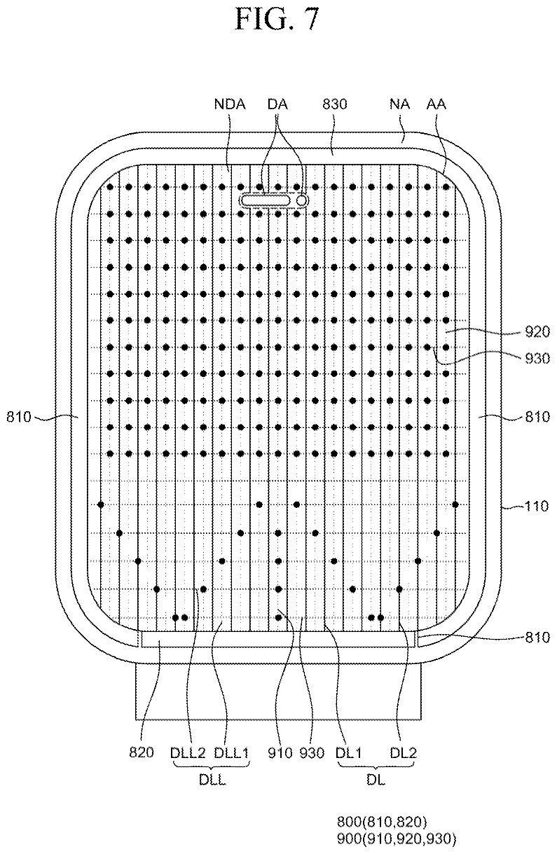

FIG. 7 is a plan view of a display panel of a display device according to an exemplary aspect of the present disclosure. For the convenience of description, in FIG. 7, among various components of the display device 100, only a low potential power line 800, a low potential auxiliary line 900, and a data line DL are illustrated.

Referring to FIG. 7, the low potential power line 800 is connected to the plurality of low potential auxiliary lines 900 and is disposed in the non-active area NA of the display panel 110.

The low potential power line 800 includes a first low potential power line 810, a second low potential power line 820, and a third low potential power line 830.

The first low potential power lines 810 are connected to the plurality of low potential auxiliary lines 900 and are disposed in the non-active areas NA on both sides of the display panel 110, respectively. For example, the first low potential power lines 810 may be disposed in the non-active areas NA adjacent to both sides of the active area AA, respectively.

The second low potential power line 820 is connected to the plurality of low potential auxiliary lines 900 and is disposed in the non-active area NA on one side of the display panel 110. For example, the second low potential power line 820 may be disposed in the non-active area NA adjacent to a lower end of the active area AA.

The third low potential power line 830 is connected to the plurality of low potential auxiliary lines 900 and is disposed in the non-active area NA on the other side of the display panel 110. For example, the third low potential power line 830 may be disposed in the non-active area NA adjacent to an upper end of the active area AA.

Therefore, in the entire non-active area NA which encloses the active area AA, the first low potential power line 810, the second low potential power line 820, and the third low potential power line 830 are disposed, respectively, to enclose the active area AA.

The first low potential power line 810, the second low potential power line 820, and the third low potential power line 830 may be formed of the same material. For example, the first low potential power line 810, the second low potential power line 820, and the third low potential power line 830 may be formed of the same material as the source electrodes 203 and 403 and the drain electrodes 204 and 404 of the thin film transistors 200 and 400 disposed in the active area AA and may be disposed on the same layer.

Referring to FIG. 7, a plurality of data lines DL and a plurality of data link lines DLL are disposed in the active area AA of the display panel 110.

The plurality of data lines DL is disposed in the active area AA of the display panel 110 to supply a data voltage to the pixel PX. The plurality of data lines DL includes a plurality of first data lines DL1 and a plurality of second data lines DL2.

The plurality of first data lines DL1 may be disposed in the active area AA to be corresponding to the driving integrated circuit D-IC. Therefore, the plurality of first data lines DL1 may be disposed in an area corresponding to a width of the driving integrated circuit D-IC. For example, when the driving integrated circuit D-IC is disposed in the center of the display panel 110, the plurality of first data lines DL1 is disposed in a vertical direction along the center of the display panel 110 corresponding to the driving integrated circuit D-IC. The plurality of first data lines DL1 may not be disposed at the outer periphery of the display panel 110 excluding the center of the display panel 110. The plurality of first data lines DL1 may be connected to the plurality of pixels PX without a separate link line. That is, the plurality of first data lines DL1 extends from the driving integrated circuit D-IC to be directly connected to the plurality of pixels PX.

The plurality of second data lines DL2 is disposed at the outside of the plurality of first data lines DL1. For example, when the plurality of first data lines DL1 is disposed in the center of the substrate 111, the plurality of second data lines DL2 may be disposed at the outer periphery of the substrate 111. The plurality of second data lines DL2 may be connected to the plurality of sub pixels SP through the plurality of data link lines DLL. That is, the plurality of second data lines DL2 may be connected to the plurality of sub pixels SP through the plurality of data link lines DLL extending from the driving integrated circuit D-IC.

The plurality of first data lines DL1 and the plurality of second data lines DL2 may be formed of the same material as the source electrodes 203 and 403 and the drain electrodes 204 and 404 of the thin film transistors 200 and 400 disposed in the active area AA and may be disposed on the same layer. For example, the plurality of first data lines DL1 and the plurality of second data lines DL2 may be a single layer or multiple layers formed of any one of molybdenum (Mo), aluminum (Al), chrome (Cr), gold (Au), titanium (Ti), nickel (Ni), neodymium (Nd), and copper (Cu) or an alloy thereof, but is not limited thereto.

Referring to FIG. 7, the plurality of data link lines DLL is disposed in the active area AA to transmit the data voltage to the plurality of data lines DL. The plurality of data link lines DLL includes first data link lines DLL1 and second data link lines DLL2.

The first data link lines DLL1 are disposed between the plurality of first data lines DL1. The first data link lines DLL1 extend from the driving integrated circuit D-IC to be straightly disposed in the active area AA. For example, the plurality of first data link lines DLL1 may be disposed to be spaced apart from the driving integrated circuit D-IC with a predetermined interval in an area corresponding to the width of the driving integrated circuit D-IC. Further, the plurality of first data link lines DLL1 may be disposed to be parallel to the plurality of first data lines DL1 between the plurality of first data lines DL1. Therefore, when the driving integrated circuit D-IC is disposed in the center of the display panel 110, the plurality of first data link lines DLL1 may be disposed in the center of the display panel 110, but may be not disposed at the outer periphery of the display panel 110.

The plurality of second data link lines DLL2 is connected to the plurality of first data link lines DLL1 and is disposed to intersect the plurality of first data link lines DLL1. For example, the plurality of second data link lines DLL2 is connected to ends of the plurality of first data link lines DLL1 and may be disposed to extend to both outer peripheral directions of the display panel 110 which are perpendicular to the plurality of first data link lines DLL1. Further, the plurality of second data link lines DLL2 extending in both outer peripheral directions of the display panel 110 may be connected to the second data lines DL2, respectively.

At this time, a signal applied from the driving integrated circuit D-IC may be transmitted to the second data line DL2 through the plurality of first data link lines DLL1 and the plurality of second data link lines DLL2 disposed in the active area AA.

The plurality of second data link lines DLL2 may be formed of the same material as the source electrodes 203 and 403 and the drain electrodes 204 and 404 of the thin film transistors 200 and 400 disposed in the active area AA and may be disposed on the same layer. For example, the plurality of second data link lines DLL2 may be a single layer or multiple layers formed of one of molybdenum (Mo), aluminum (Al), chrome (Cr), gold (Au), titanium (Ti), nickel (Ni), neodymium (Nd), and copper (Cu) or an alloy thereof, but is not limited thereto.

The plurality of first data link lines DLL1 may be disposed on the first planarization layer 118 and may be formed of a conductive material, such as copper (Cu), silver (Ag), molybdenum (Mo) and titanium (Ti).

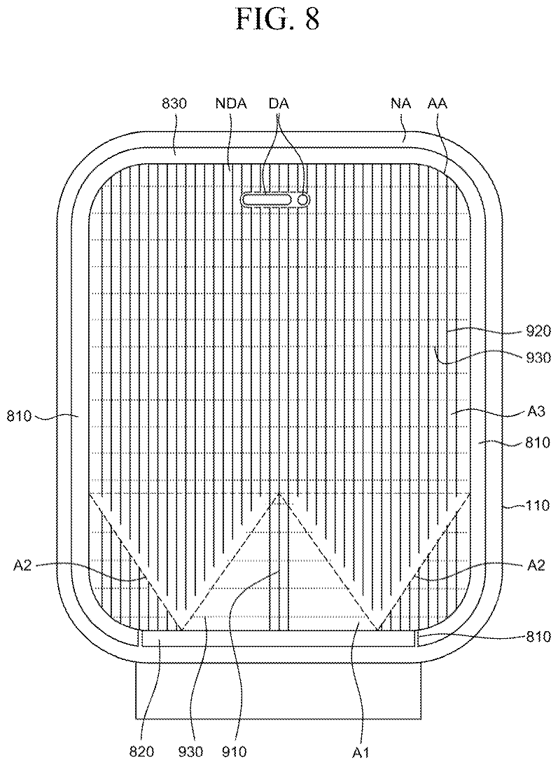

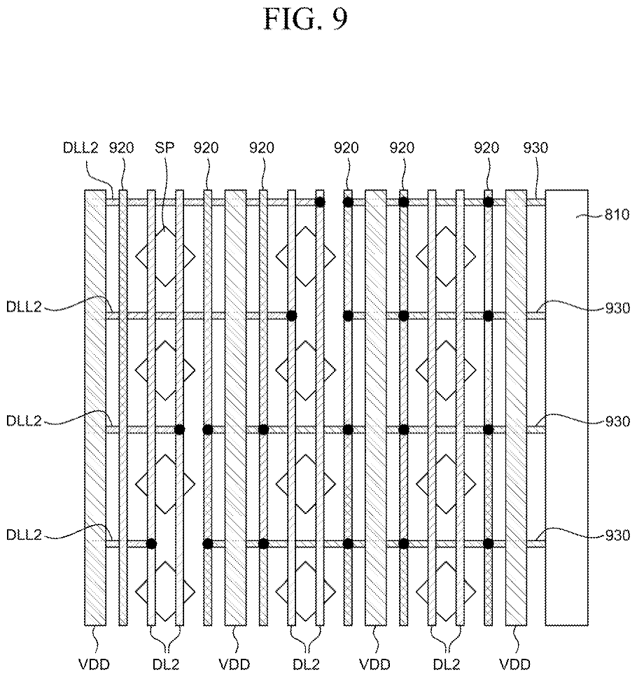

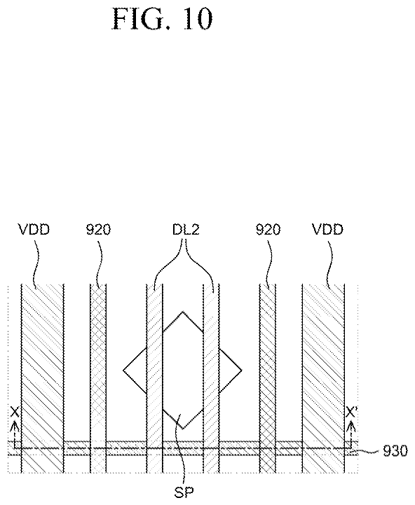

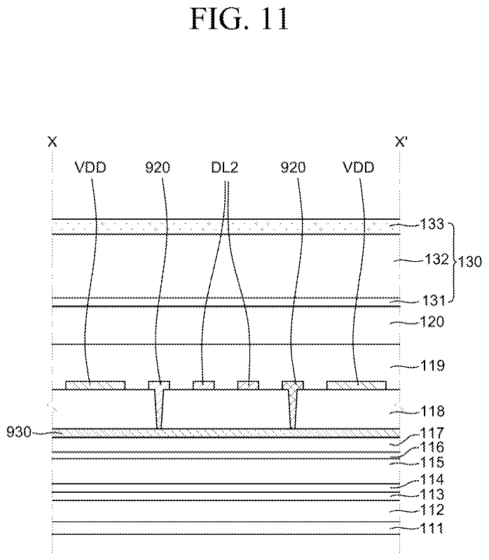

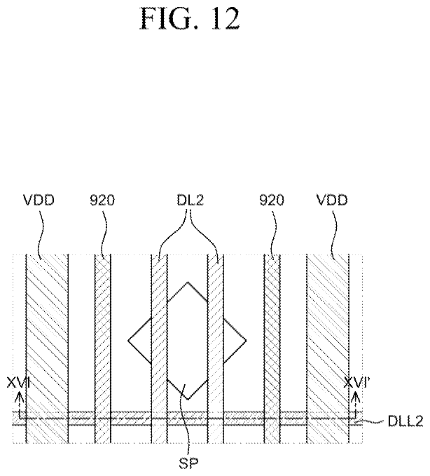

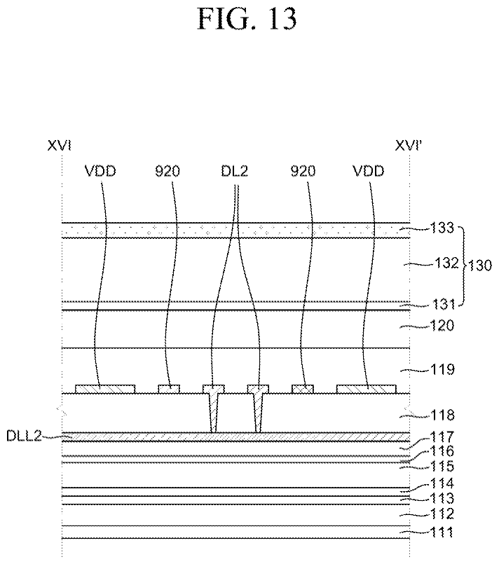

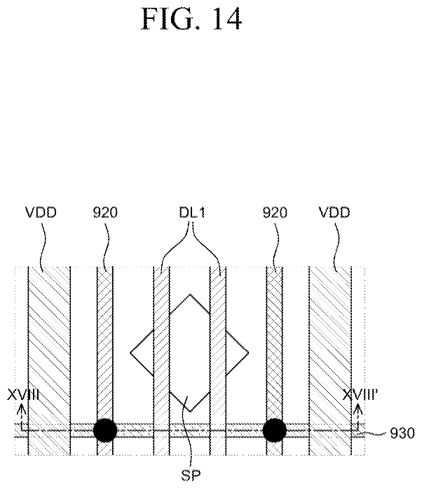

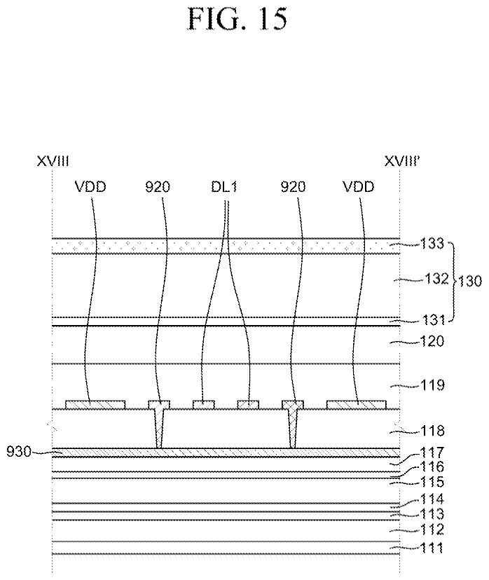

FIG. 8 is a plan view illustrating a low potential auxiliary line in a display panel of a display device according to an exemplary aspect of the present disclosure. FIG. 9 is an enlarged view of a part of a display panel of a display device according to an exemplary aspect of the present disclosure. FIG. 10 is an enlarged view illustrating part A1 of FIG. 8. FIG. 11 is a cross-sectional view taken along line X-X′ of FIG. 10. FIG. 12 is an enlarged view illustrating part A2 of FIG. 8. FIG. 13 is a cross-sectional view taken along line XVI-XVI′ of FIG. 12. FIG. 14 is an enlarged view illustrating part A3 of FIG. 8. FIG. 15 is a cross-sectional view taken along line XVIII-XVIII′ of FIG. 14. For the convenience of description, in FIG. 8, among various components of the display device 100, only a low potential power line 800 and a low potential auxiliary line 900 are illustrated. FIG. 9 illustrates an area in which the first area A1 and the second area A2 are in contact with each other.

Referring to FIGS. 8 and 9, the first low potential power line 810, the second low potential power line 820, and the third low potential power line 830 are connected to the plurality of low potential auxiliary lines 900, respectively. The plurality of low potential auxiliary lines 900 is disposed in the active area AA and supplies a high potential voltage to the plurality of pixels PX. The plurality of low potential auxiliary lines 900 includes at least one first low potential auxiliary line 910, a plurality of second low potential auxiliary lines 920, and a plurality of third low potential auxiliary lines 930.

The first low potential auxiliary line 910 is disposed in the same direction as the plurality of data lines DL. One side of the first low potential auxiliary line 910 is connected to the second low potential power line 820 and the other side is connected to the third low potential power line 830. For example, at least one first low potential auxiliary line 910 may be disposed in the center of the display panel 110 and may be straightly disposed between the second low potential power line 820 and the third low potential power line 830 in the active area AA.

The plurality of second low potential auxiliary lines 920 is disposed in the same direction as the plurality of data lines DL. The plurality of second low potential auxiliary lines 920 is disposed between the high potential power line VDD and the data line DL2. One ends of the plurality of second low potential auxiliary lines 920 are connected to the second low potential power line 820 and the other ends are connected to the third low potential power line 830. For example, the plurality of second low potential auxiliary lines 920 may be straightly disposed between the second low potential power line 820 and the third low potential power line 830 in the active area AA. Further, the plurality of second low potential auxiliary lines 920 may be disposed between the high potential power line VDD and the data line DL2 to be spaced apart from the high potential power line VDD and the data line DL2 with a predetermined interval in parallel therewith.

The plurality of third low potential auxiliary lines 930 is connected to the plurality of second low potential auxiliary lines 920 and intersects the plurality of second low potential auxiliary lines 920. Both ends of the plurality of third low potential auxiliary lines 930 are connected to the first low potential power lines 810 disposed in both non-active areas NA of the display panel 110, respectively. For example, the plurality of third low potential auxiliary lines 930 may be straightly disposed in the active area AA between the first low potential power lines 810 disposed in both non-active areas NA of the display panel 110. Further, the plurality of third low potential auxiliary lines 930 is disposed to be perpendicular to the plurality of second low potential auxiliary lines 920 to be connected with each other or spaced apart from each other with a predetermined interval. Therefore, the plurality of second low potential auxiliary lines 920 and the plurality of third low potential auxiliary lines 930 may be disposed in the active area AA in a matrix.

Referring to FIG. 9, the plurality of sub pixels SP is disposed in the active area AA. The plurality of sub pixels SP may be sub-pixels SP for emitting different color light. For example, the plurality of sub pixels SP may be a red sub pixel, a green sub pixel, a blue sub pixel, and a white sub pixel, respectively, but is not limited thereto. The plurality of sub pixels SP may configure a pixel PX. That is, the red sub pixel, the green sub pixel, the blue sub pixel, and the white sub pixel may configure one pixel PX and the display panel 110 may include a plurality of pixels PX. In the exemplary aspect of the present disclosure, for the convenience of description, it is illustrated that one pixel PX includes one sub pixel SP.

Referring to FIG. 9, in the active area AA, the plurality of high potential power lines VDD is disposed in the same direction as the plurality of data lines DL. For example, the plurality of high potential power lines VDD is straightly disposed in the active area and spaced apart from each other with a predetermined interval to be parallel.

Referring to FIG. 9, the second data line DL2 is disposed to overlap the plurality of sub pixels SP. The second data line DL2 is disposed above the plurality of sub pixels SP. The second low potential auxiliary line 920 is disposed between the second data line DL2 and the high potential power line VDD. That is, the second low potential auxiliary line 920 is disposed at the outside of the second data line DL2 so as not to overlap the plurality of sub pixels SP. The first low potential auxiliary line 910, the plurality of second low potential auxiliary lines 920, and the plurality of third low potential auxiliary lines 930 are disposed in different manners depending on areas of the display panel 110.

Referring to FIG. 8, the display panel 110 includes a first area A1 which is an active area AA in which the first data link line DLL1 is disposed, a second area A2 which is an active area AA in which the second data link line DLL2 is disposed, and a third area A3 which is the remaining active area AA other than the first area A1 and the second area A2.

Referring to FIGS. 7 and 8, the first area A1 is an area in which the first data link line DLL1 is disposed. For example, the first area A1 may be a triangular area in the center of one side of the display panel 110.

Referring to FIGS. 8 and 10, in the first area A1, the first low potential auxiliary line 910 and the third low potential auxiliary line 930 are disposed. In the first area A1, the first low potential auxiliary line 910 connected between the second low potential power line 820 and the third low potential power line 830 is disposed. In the first area A1, the first low potential auxiliary line 910 is connected to the third low potential auxiliary line 930 disposed in a direction intersecting the first low potential auxiliary line 910. For example, in the first area A1, one first low potential auxiliary line 910 may be disposed in the center of the display panel 110 and the plurality of third low potential auxiliary line 930 is disposed in a direction perpendicular to the first low potential auxiliary line 910 to be connected.

Referring to FIG. 11, in the first area A1, the high potential power line VDD, the first data link line DLL1, and the second data line DL2 may be formed of the same material and may be disposed on the same layer. For example, the high potential power line VDD, the first data link line DLL1, and the second data line DL2 may be formed of the same material as the source electrodes 203 and 403 and the drain electrodes 204 and 404 of the thin film transistors 200 and 400 disposed in the active area AA and may be disposed on the same layer. In the first area A1, the third low potential auxiliary line 930 may be disposed on lower layers of the high potential power line VDD, the first data link line DLL1, and the second data line DL2.

Referring to FIG. 8, the second area A2 is an area in which the second data link line DLL2 is disposed. For example, the second areas A2 may be inverted triangular area disposed on both sides of the first area A1.

Referring to FIGS. 8 and 12, the plurality of second low potential auxiliary lines 920 is disposed in the second area A2. For example, in the second area A2, the plurality of second low potential auxiliary lines 920 connected to the third low potential power line 830 may be disposed with a predetermined interval. For example, in the second area A2, the plurality of second low potential auxiliary lines 920 connected to the third low potential power line 830 is spaced apart from the data line DL with a predetermined interval to be parallel. For example, the second low potential auxiliary lines 920 may be disposed between the data line DL and the high potential power line VDD. For example, the plurality of second low potential auxiliary lines 920 disposed in the second area A2 may be connected to the plurality of second low potential auxiliary lines 920 disposed in the third area A3.

Referring to FIG. 13, in the second area A2, the high potential power line VDD, the second low potential auxiliary line 920, and the second data line DL2 may be formed of the same material and may be disposed on the same layer. For example, the high potential power line VDD, the second low potential auxiliary line 920, and the second data line DL2 may be formed of the same material as the source electrodes 203 and 403 and the drain electrodes 204 and 404 of the thin film transistors 200 and 400 disposed in the active area AA and may be disposed on the same layer. In the second area A2, the second data link line DLL2 is disposed on lower layers of the high potential power line VDD, the second low potential auxiliary line 920, and the second data line DL2. In the second area A2, the second data line DL2 is electrically connected to the second data link line DLL2 through a contact hole.

Referring to FIG. 8, the third area A3 is a remaining area other than the first area A1 and the second area A2. For example, the third area A3 may be both lower corner areas of the display panel 110 and the remaining area excluding a part of the lower portion of the display panel 110 in which the first area A1 and the second areas A2 are disposed.

Referring to FIGS. 8 and 14, in the third area A3, the plurality of second low potential auxiliary lines 920 and the plurality of third low potential auxiliary lines 930 are disposed. In the third area A3, the second low potential auxiliary lines 920 is connected to the third low potential auxiliary lines 930. In the third area A3, the plurality of second low potential auxiliary lines 920 is disposed in the same direction as the first data line DL1. For example, the plurality of second low potential auxiliary lines 920 may be disposed with a predetermined interval and the plurality of third low potential auxiliary lines 930 is disposed in a direction intersecting the plurality of second low potential auxiliary lines 920 to be connected to the second low potential auxiliary lines 920. Therefore, in the third area A3, the plurality of second low potential auxiliary lines 920 and the plurality of third low potential auxiliary lines 930 may be disposed in a matrix.

Referring to FIG. 15, in the third area A3, the high potential power line VDD, the second low potential auxiliary line 920, and the first data line DL1 may be formed of the same material and may be disposed on the same layer. For example, the high potential power line VDD, the second low potential auxiliary line 920, and the first data line DL1 may be formed of the same material as the source electrodes 203 and 403 and the drain electrodes 204 and 404 of the thin film transistors 200 and 400 disposed in the active area AA and may be disposed on the same layer. In the third area A3, the third low potential auxiliary line 930 is disposed on lower layers of the high potential power line VDD, the second low potential auxiliary line 920, and the first data line DL1. In the third area A3, the second low potential auxiliary line 920 is electrically connected to the third low potential auxiliary line 930 through a contact hole.

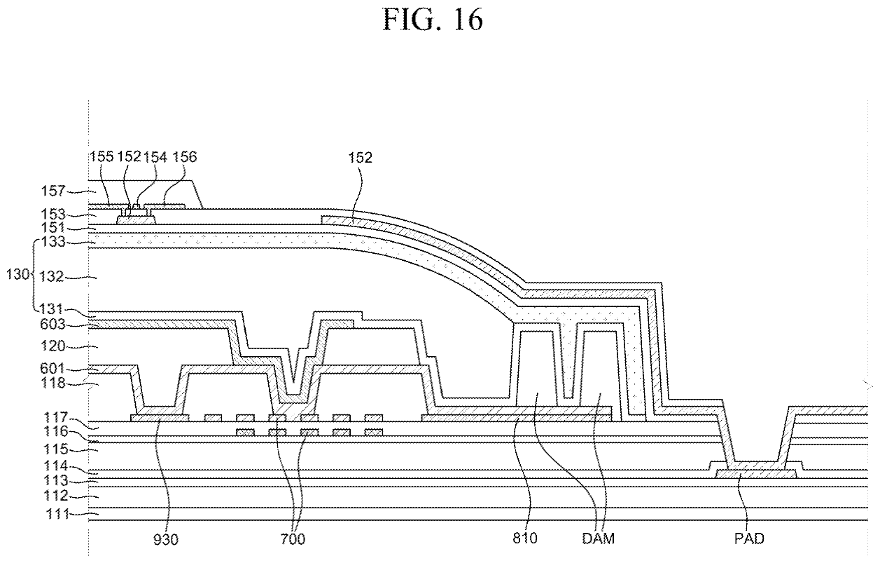

FIG. 16 is a cross-sectional view of an outer periphery of a display panel of a display device according to an exemplary aspect of the present disclosure. FIG. 16 is a cross-sectional view of an outer periphery of the display panel 110 so that the same configuration as that in FIG. 3 will not be described.

Referring to FIG. 16, when the organic encapsulating layer 132 is formed using an inkjet method, a dam DAM may be disposed to suppress a liquefied organic encapsulating layer 132 from being diffused to an edge of the substrate 111. The dam DAM may be disposed to be closer to the edge of the substrate 111 than the organic encapsulating layer 132. The dam DAM may suppress the organic encapsulating layer 132 from being diffused into a pad region where a conductive pad PAD disposed at an outermost periphery of the substrate 111 is disposed.

The dam DAM may be disposed on the second interlayer insulating layer 117 of the non-active area NA.

Further, the dam DAM may be simultaneously formed with the first planarization layer 118. When the first planarization layer 118 is formed, the dam DAM may be formed together. Therefore, the dam DAM may be formed of the same material as the first planarization layer 118, but is not limited thereto.

The dam DAM may be formed to overlap the first low potential power line 810. For example, on a lower layer of a region of the non-active area NA where the dam DAM is located, the first low potential power line 810 may be formed.

The first low potential power line 810 and the gate driver 700 configured in a gate-in-panel (GIP) manner are formed to enclose the outer periphery of the display panel and the first low potential power line 810 may be located at the outer periphery more than the gate driver 700. Further, the first low potential power line 810 is connected to the cathode electrode 603 through the anode electrode 601 to apply a common voltage. Even though the gate driver 700 is simply illustrated in a plan view and a cross-sectional view, the gate driver 700 may be configured using a thin film transistor having the same structure as the thin film transistor of the active area AA.

The first low potential power line 810 is disposed at the outside more than the gate driver 700. The first low potential power line 810 is disposed at the outside more than the gate driver 700 and encloses the active area AA. For example, the first low potential power line 810 may be formed of the same material as the second electrode 302 or the first source electrode 203 and the first drain electrode 204, but is not limited thereto and may be formed of the same material as the first gate electrode 202.

The plurality of third low potential auxiliary lines 930 and the plurality of first low potential power lines 810 are electrically connected through the anode electrode 601. For example, the third low potential auxiliary line 930 may be electrically connected to the anode electrode 601 disposed on the planarization layer 118 and the anode electrode 601 may be electrically connected to the cathode electrode 603 disposed thereabove. Further, the anode electrode 601 which outwardly extends may be electrically connected to the plurality of first low potential power lines 810. Therefore, the plurality of third low potential auxiliary lines 930 and the plurality of first low potential power lines 810 may be electrically connected through the anode electrode 601.

A touch layer may be disposed on the encapsulation layer 130. A touch buffer film 151 may be disposed between a touch sensor metal including touch electrode connection lines 152 and 154 and touch electrodes 155 and 156 and a cathode electrode 603 of the light emitting diode 600 on the touch layer.

The touch buffer film 151 may suppress the permeation of a chemical solution (a developer, an etchant, or the like) used for a manufacturing process of a touch sensor metal disposed on the touch buffer film 151 or moisture from the outside into the emission layer 602 including an organic material. By doing this, the touch buffer film 151 may suppress the damage of the emission layer 602 which is vulnerable to the chemical solution or the moisture.

The touch buffer film 151 may be formed of an organic insulating material which is formed at a temperature lower than a predetermined temperature (for example, 100° C.) to suppress the damage of the emission layer 602 including an organic material which is vulnerable to a high temperature. The organic insulating material has a low permittivity of 1 to 3. For example, the touch buffer film 151 may be formed of an acrylic, epoxy, or siloxane-based material. The touch buffer film 151 which is formed of an organic insulating material and has a planarization performance may suppress a damage of the encapsulation layer 130 caused by the bending of the organic light emitting display device and the breakage of the touch sensor metal formed on the touch buffer film 151.

According to a mutual-capacitance-based touch sensor structure, the touch electrodes 155 and 156 are disposed on the touch buffer film 151 and the touch electrodes 155 and 156 may be alternately disposed.

The touch electrode connection lines 152 and 154 may electrically connect the touch electrodes 155 and 156. The touch electrode connection lines 152 and 154 and the touch electrodes 155 and 156 may be disposed on different layers with the touch insulating film 153 therebetween.

The touch electrode connection lines 152 and 154 are disposed to overlap the bank layer 120 to suppress the degradation of the aperture ratio.

In the meantime, in the touch electrodes 155 and 156, a part of the touch electrode connection line 152 passes through an upper portion and a side surface of the encapsulation layer 130 and an upper portion and a side surface of the dam DAM to be electrically connected to a touch driving circuit (not illustrated) through the touch pad PAD.

A part of the touch electrode connection line 152 is supplied with a touch driving signal from the touch driving circuit to transmit the touch driving signal to the touch electrodes 155 and 156 and transmit a touch sensing signal in the touch electrodes 155 and 156 to the touch driving circuit.

A touch protection film 157 may be disposed on the touch electrodes 155 and 156. In the drawing, even though it is illustrated that the touch protection film 157 is disposed only on the touch electrodes 155 and 156, it is not limited thereto and the touch protection film 157 extends before and after the dam DAM to be also disposed on the touch electrode connection line 152.

A color filter (not illustrated) may be further disposed on the encapsulation layer 130 and the color filter may be disposed on the touch layer or located between the encapsulation layer 130 and the touch layer.

Accordingly, in the display device 100 according to the exemplary aspect of the present disclosure, the data link line DLL is disposed in the active area AA so that the bezel area of the display device 100 may be reduced. In the meantime, the data link line DLL which connects the data line DL disposed at the outer periphery of the display panel 110 among the plurality of data lines DL and the driving integrated circuit D-IC may be disposed in the non-active area NA between the active area AA and the bending area BA. In this case, the reduction of the bezel area of the display device 100 is restricted and the implementation of the display device 100 with a high resolution is difficult. In contrast, in the display device 100 according to the exemplary aspect of the present disclosure, the data link line DLL which connects the data line DL disposed at the outer periphery of the display panel 110 and the driving integrated circuit D-IC is disposed in the active area AA. Therefore, the non-active area NA disposed between the active area AA and the bending area BA is reduced to minimize the bezel area.

Further, in the display device 100 according to the exemplary aspect of the present disclosure, the low potential power line 800 is disposed to enclose the active area AA along the non-active area NA so that the bezel area of the display device 100 may be reduced. In the meantime, the low potential power line 800 may be disposed only at one side of the non-active area NA. In this case, an area of the low potential power line 800 should be increased so that the reduction in the bezel area of the display device 100 is restricted and the implementation of the display device 100 with a high resolution is difficult. In contrast, in the display device 100 according to the exemplary aspect of the present disclosure, the low potential power line 800 is disposed to enclose the active area AA along the non-active area NA so that a width of the low potential power line 800 may be reduced while maintaining the entire area of the low potential power line 800. Accordingly, the non-active area NA may be reduced to minimize the bezel area.

Further, in the display device 100 according to the exemplary aspect of the present disclosure, the low potential auxiliary line 900 is additionally disposed in the active area AA to additionally apply a low potential power so that the voltage rising is improved to improve the imbalance of the color and the luminance. In the meantime, only one low potential auxiliary line 910 is disposed in the active area AA of the display panel 110. In this case, a low potential power which is applied through one side increases the voltage at the other side due to the internal resistance. In the meantime, in the display device 100 according to the exemplary aspect of the present disclosure, the low potential auxiliary line 900 is additionally disposed in the active area AA to additionally apply a low potential power so that the voltage rising generated at the other side area is improved to improve the imbalance of the color and the luminance.

The exemplary embodiments of the present disclosure may also be described as follows:

A display device according to an exemplary aspect of the present disclosure includes a display panel including an active area in which a plurality of pixels is disposed and a non-active area disposed to enclose the active area, a plurality of low potential auxiliary lines disposed in the active area, a plurality of low potential power lines which is connected to the plurality of low potential auxiliary lines and is disposed in the non-active area of the display panel, a plurality of data lines disposed in the active area and a plurality of data link lines which is disposed in the active area and transmits a data voltage to the plurality of data lines.

The plurality of low potential power lines may include a first low potential power line which are connected to the plurality of low potential auxiliary lines and are disposed in non-active areas on both sides of the display panel, respectively.

The plurality of low potential power lines may further include a second low potential power line which is connected to the plurality of low potential auxiliary lines and is disposed in the non-active area on one side of the display panel, and a third low potential power line which is connected to the plurality of low potential power lines and is disposed in the non-active area on the other side of the display panel.

The plurality of data link lines may be formed of the same material as the plurality of low potential auxiliary lines.

The plurality of data link lines and the plurality of low potential auxiliary lines may be formed of the same material as the plurality of low potential power lines.

The display device may further include a plurality of transistors disposed in the active area, the plurality of data link lines, the plurality of low potential auxiliary lines, and the low potential power lines may be formed of the same material as source electrodes and drain electrodes of the plurality of transistors.

The plurality of data link lines may include a plurality of first data link lines disposed in the same direction as the plurality of data lines and a second data link line which is connected to the plurality of first data link lines and is disposed to intersect the plurality of first data link lines.

The plurality of low potential auxiliary lines may include at least one first low potential auxiliary line disposed in the same direction as the plurality of data lines, a plurality of second low potential auxiliary lines disposed in the same direction as the plurality of data lines and a plurality of third low potential auxiliary lines which is connected to the plurality of second low potential auxiliary lines and is disposed to intersect the plurality of second low potential auxiliary lines.

The display device may include a first area which is the active area in which the first data link line is disposed, a second area which is the active area in which the second data link line is disposed, a third area which is the remaining active area other than the first area and the second area.

In the first area, the at least one first low potential auxiliary line and the plurality of third low potential auxiliary lines may be disposed.

In the second area, the plurality of second low potential auxiliary lines may be disposed.

In the third area, the plurality of second low potential auxiliary lines and the plurality of third low potential auxiliary lines may be disposed.

In the third area, the plurality of second low potential auxiliary lines and the plurality of third low potential auxiliary lines may be disposed in a matrix.

The display device may further include a plurality of light emitting diodes disposed in the active area, the low potential power line is connected to the low potential auxiliary line through anode electrodes of the plurality of light emitting diodes.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a display panel including an active area in which a plurality of pixels is disposed and a non-active area enclosing the active area;
a plurality of low potential auxiliary lines disposed in the active area;
a plurality of low potential power lines connected to the plurality of low potential auxiliary lines and disposed in the non-active area of the display panel;
a plurality of data lines disposed in the active area; and
a plurality of data link lines disposed in the active area and configured to transmit a data voltage to the plurality of data lines.

2. The display device according to claim 1, wherein the plurality of low potential power lines includes a first low potential power line connected to the plurality of low potential auxiliary lines and disposed in non-active areas on both sides of the display panel.

3. The display device according to claim 2, wherein the plurality of low potential power lines further includes:
a second low potential power line connected to the plurality of low potential auxiliary lines and disposed in the non-active area on one side of the display panel; and
a third low potential power line connected to the plurality of low potential power lines and disposed in the non-active area on another side of the display panel.

4. The display device according to claim 1, wherein the plurality of data link lines is formed of a same material as the plurality of low potential auxiliary lines.

5. The display device according to claim 4, wherein the plurality of data link lines and the plurality of low potential auxiliary lines are formed of a same material as the plurality of low potential power lines.

6. The display device according to claim 5, further comprising a plurality of transistors disposed in the active area,
wherein the plurality of data link lines, the plurality of low potential auxiliary lines, and the low potential power lines are formed of a same material as source electrodes and drain electrodes of the plurality of transistors.

7. The display device according to claim 1, wherein the plurality of data link lines includes:
a plurality of first data link lines disposed in a same direction as the plurality of data lines; and
a second data link line connected to the plurality of first data link lines and disposed to intersect the plurality of first data link lines.

8. The display device according to claim 7, wherein the plurality of low potential auxiliary lines includes:
at least one first low potential auxiliary line disposed in a same direction as the plurality of data lines;
a plurality of second low potential auxiliary lines disposed in a same direction as the plurality of data lines; and
a plurality of third low potential auxiliary lines connected to the plurality of second low potential auxiliary lines and disposed to intersect the plurality of second low potential auxiliary lines.

9. The display device according to claim 8, wherein the active area in which the first data link line is disposed is defined as a first area, the active area in which the second data link line is disposed is defined as a second area, and a remaining active area other than the first area and the second area is defined as a third area.

10. The display device according to claim 9, wherein the at least one first low potential auxiliary line and the plurality of third low potential auxiliary lines are disposed in the first area.

11. The display device according to claim 9, wherein the plurality of second low potential auxiliary lines is disposed in the second area.

12. The display device according to claim 9, wherein the plurality of second low potential auxiliary lines and the plurality of third low potential auxiliary lines are disposed in the third area.

13. The display device according to claim 12, wherein the plurality of second low potential auxiliary lines and the plurality of third low potential auxiliary lines are disposed in a matrix in the third area.

14. The display device according to claim 1, further comprising a plurality of light emitting diodes disposed in the active area,
wherein the low potential power line is connected to the low potential auxiliary line through anode electrodes of the plurality of light emitting diodes.

15. A display device, comprising:
a display panel including an active area in which a plurality of pixels are disposed and a non-active area disposed around the active area;
a plurality of low potential power lines disposed around active area and disposed in the non-active area;
a plurality of low potential auxiliary lines disposed in the active area connected to at least one of the plurality low potential power lines;
a plurality of data lines disposed in the active area; and
a plurality of data link lines disposed in the active area and configured to transmit a data voltage to the plurality of data lines.

16. The display device according to claim 15, wherein the plurality of low potential auxiliary lines includes a plurality of first low potential auxiliary lines and a plurality second low potential auxiliary lines arranged in a matrix form.

17. The display device according to claim 16, the plurality of first low potential auxiliary lines are connected to the plurality of low potential power lines, and
wherein the plurality second low potential auxiliary lines are the plurality of first low potential auxiliary lines.
